(19) United States
(12) Patent Application Publication
(10) Pub. No.: US 2022/0367154 A1
(43) Pub. Date: Nov. 17, 2022

(54) PLASMA PROCESSING APPARATUS

(71) Applicant: TOKYO ELECTRON LIMITED, Tokyo (JP)

(72) Inventors: Masakatsu KASHIWAZAKI, Kurokawa-gun (JP); Toshifumi ISHIDA, Kurokawa-gun (JP); Hirofumi OHTA, Kurokawa-gun (JP)

(73) Assignee: TOKYO ELECTRON LIMITED, Tokyo (JP)

(21) Appl. No.: 17/815,525

(22) Filed: Jul. 27, 2022

Related U.S. Application Data
(63) Continuation of application No. 16/009,742, filed on Jun. 15, 2018.

(30) Foreign Application Priority Data
Jun. 21, 2017 (JP) 2017-121550

(51) Int. Cl. H01J 37/32

(52) U.S. Cl. CPC H01J 37/32633; H01J 37/32733; H01J 37/32834; H01J 37/3244

(57) ABSTRACT

A plasma processing apparatus according to one aspect includes a chamber body providing a chamber, the chamber body including a side wall, an opening being formed on the side wall, a stage provided in the chamber, a ceiling facing the stage, a gas supply system configured to supply a processing gas to the chamber, a power supply configured to supply electric power, and a wall that forms a processing space having a volume smaller than a volume of the chamber in the chamber. At least a part of the wall is movable between a position overlapping with a transport path extending between the processing space and the opening and a position not overlapping with the transport path, and the wall forms the processing space when the at least a part of the wall is disposed at the position overlapping with the transport path.

### CROSS-REFERENCE TO RELATED APPLICATIONS

This application is a Continuation of U.S. patent application Ser. No. 16/009,742 filed Jun. 15, 2018, which is based on and claims the benefit of priority from Japanese Patent Application No. 2017-121550 filed on Jun. 21, 2017, the entire contents of which are incorporated herein by reference.

### TECHNICAL FIELD

Exemplary embodiments of the present disclosure relate to a plasma processing apparatus.

### BACKGROUND

In manufacturing an electronic device such as a semiconductor device, a plasma processing apparatus is used for processing such as etching and film deposition. For example, Japanese Unexamined Patent Publication No. 2015-109479 discloses a plasma etching apparatus including a chamber body, a lower electrode, and an upper electrode. The upper electrode and the lower electrode are disposed so as to face each other. In the plasma processing apparatus, a gas is supplied to the chamber and a high frequency electric field is formed between the upper electrode and the lower electrode. The gas is excited by the high frequency electric field to generate plasma. A workpiece is etched by an ion and/or a radical from the plasma.

### SUMMARY

A plasma processing apparatus according to one aspect includes a chamber body providing a chamber, the chamber body including a side wall having an opening though which a workpiece is carried into the chamber or carried out from the chamber, a stage provided in the chamber, a ceiling facing the stage, a gas supply system configured to supply a processing gas to the chamber, a power supply configured to supply electric power for generating plasma of the processing gas, and a wall that forms a processing space having a volume smaller than a volume of the chamber in the chamber, in which the processing space includes a space between the stage and the ceiling. At least a part of the wall is movable between a position overlapping with a transport path extending between the processing space and the opening and a position not overlapping with the transport path, and the wall forms the processing space when the at least a part of the wall is disposed at the position overlapping with the transport path.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a cross-sectional view schematically illustrating a configuration of a plasma processing apparatus according to one exemplary embodiment.

FIG. 2 is a perspective view illustrating a part of a plasma processing apparatus according to a first exemplary embodiment in a broken manner.

FIG. 3 is a plan view of a stage and a wall of the plasma processing apparatus illustrated in FIG. 2 as viewed from above.

FIG. 4 is a perspective view illustrating the part of the plasma processing apparatus according to the first exemplary embodiment in a broken manner.

FIG. 5 is a plan view of the stage and the wall of the plasma processing apparatus illustrated in FIG. 4 as viewed from above.

FIG. 6 is a plan view of a stage and a wall of a plasma processing apparatus according to a second exemplary embodiment as viewed from above.

FIG. 7 is a perspective view illustrating a joint portion between a first end portion of a curved plate and a slider.

FIG. 8A is a plan view illustrating the first end portion and a second end portion of the plurality of curved plates.

FIG. 8B is a plan view illustrating the first end portion and a second end portion of the plurality of curved plates.

FIG. 9 is a perspective view schematically illustrating a movement mechanism.

FIG. 10 is a plan view of the stage and the wall of the plasma processing apparatus according to the second exemplary embodiment as viewed from above.

FIG. 11 is a plan view of the stage and the wall of the plasma processing apparatus according to the second exemplary embodiment as viewed from above.

FIG. 12 is a perspective view illustrating a part of a plasma processing apparatus according to a third exemplary embodiment in a broken manner.

FIG. 13 is a perspective view illustrating the part of the plasma processing apparatus according to the third exemplary embodiment in a broken manner.

FIG. 14 is a cross-sectional view schematically illustrating a configuration of the plasma processing apparatus illustrated in FIG. 13.

FIG. 15 is a perspective view illustrating a part of a plasma processing apparatus according to a modification example in a broken manner.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

In one aspect, in a case of processing the workpiece using such the plasma processing apparatus, it is required to generate high density plasma in a space between the upper electrode and the lower electrode in order to improve processing efficiency of the workpiece. The plasma density can be increased when electric power supplied to the plasma processing apparatus increases. However, the increase in the supplied electric power increases a manufacturing cost of the electronic device.

Therefore, it is required to improve the plasma density per unit supply electric power in the technical field.

A plasma processing apparatus according to one aspect includes a chamber body providing a chamber, the chamber body including a side wall having an opening through which a workpiece is carried into the chamber or carried out from the chamber, a stage provided in the chamber, a ceiling facing the stage, a gas supply system configured to supply a processing gas to the chamber, a power supply configured to supply electric power for generating plasma of the processing gas, and a wall that forms a processing space having a volume smaller than a volume of the chamber in the chamber, in which the processing space includes a space between the stage and the ceiling. At least a part of the wall is movable between a position overlapping with a transport path extending between the processing space and the opening and a position not overlapping with the transport path, and the wall forms the processing space when the at least a part of the wall is disposed at the position overlapping with the transport path.

In the plasma processing apparatus described above, since the processing space is formed when the at least a part of the wall is disposed at the position overlapping with the transport path, it is possible to limit a region where the plasma of the processing gas is generated to the processing space. Since the processing space has the volume smaller than the volume of the chamber, it is possible to enhance locality of the plasma generated in the chamber. Therefore, with the plasma processing apparatus described above, it is possible to improve the plasma density per unit electric power supplied. In the plasma processing apparatus described above, since the at least a part of the wall can be disposed at the position not overlapping with the transport path, it is possible to carry in and carry out the workpiece.

The plasma processing apparatus according to one exemplary embodiment may further include an exhaust apparatus connected to the chamber, and a plurality of through-holes through which a gas in the processing space passes may be formed in the wall. In the exemplary embodiment, it is possible to exhaust the gas in the processing space through the plurality of through-holes.

In one exemplary embodiment, the wall may include a fixed plate fixed to the position not overlapping with the transport path and a movable plate. The plasma processing apparatus further includes a movement mechanism configured to move the movable plate between the position overlapping with the transport path and the position not overlapping with the transport path. The fixed plate and the movable plate may cooperate to form a cylindrical body defining the processing space when the movable plate is disposed at the position overlapping with the transport path. In the exemplary embodiment, since the fixed plate and the movable plate cooperate to form the cylindrical body defining the processing space in the case where the movable plate is disposed at the position overlapping with the transport path, it is possible to limit the region where the plasma of the processing gas is generated to the processing space. Therefore, it is possible to improve the plasma density per unit electric power.

In one exemplary embodiment, the movement mechanism may include a base plate provided to surround a periphery of the stage, a ring-shaped guide rail provided on the base plate, a slider provided on the guide rail to be movable along the guide rail, and a motor configured to drive the movable plate. The fixed plate may be fixed on the base plate along the guide rail, and the movable plate may be connected to the slider along the guide rail. In the exemplary embodiment, it is possible to move the movable plate along the guide rail between the position overlapping with the transport path and the position not overlapping with the transport path.

In one exemplary embodiment, a base plate provided to surround a periphery of the stage, a plurality of guide rails provided on the base plate, in which each of the plurality of guide rails has one end portion and another end portion and extends in an arc shape between the one end portion and the other end portion such that a distance from a center axis of the stage increases from the one end portion toward the other end portion, wherein in each of the plurality of guide rails, the one end portion overlaps the other end portion of an adjacent guide rail among the plurality of guide rails in a radial direction with respect to the center axis, and the one end portion is located more inward than the other end portion in the radial direction, and a plurality of sliders respectively provided on the plurality of guide rails, on which each of the plurality of sliders is slidable along a corresponding guide rail among the plurality of guide rails may be further included. The wall may include a plurality of curved plates provided on the plurality of guide rails, each of the plurality of curved plates may have a first end portion and a second end portion, the first end portion of each of the plurality of curved plates may be connected to a corresponding slider among the plurality of sliders to be rotatable with a rotation axis extending in a direction parallel to the center axis as a center, and the second end portion of each of the plurality of curved plates may be a free end.

In the exemplary embodiment described above, the plurality of curved plates cooperate to form the processing space. A diameter of the processing space configured by the plurality of curved plates changes according to the positions of the first end portions of the plurality of curved plates. For example, in a case where the first end portions of the plurality of curved plates are respectively disposed on one end portions of the plurality of guide rails, the inner diameter of the cylindrical body configured by the plurality of curved plates decreases. On the other hand, in a case where the first end portions of the plurality of curved plates are respectively disposed on the other end portions of the plurality of guide rails, the inner diameter of the cylindrical body configured by the plurality of curved plates increases. Therefore, according to the exemplary embodiment described above, the volume of the processing space can be adjusted by adjusting the positions of the first end portions of the plurality of curved plates. As a result, it is possible to adjust the plasma density in the processing space.

In one exemplary embodiment, a first magnet may be provided in the first end portion, and a second magnet having a polarity different from a polarity of the first magnet may be provided in the second end portion. In the exemplary embodiment, it is possible to connect the first end portion and the second end portion of two curved plates adjacent to each other as the first magnet and the second magnet attract each other.

The plasma processing apparatus according to one exemplary embodiment may further include a ball member fixed to one end portion of the first end portion and the second end portion of each of the plurality of curved plates and configured to contact the other end portion of the first end portion and the second end portion of an adjacent curved plate among the plurality of curved plates. In the exemplary embodiment, since the ball member makes a point contact with the other end portion described above, it is possible to reduce friction force generated between the first end portion and the second end portion.

In one exemplary embodiment, an elevating mechanism configured to move the at least a part of the wall along a vertical direction between the position overlapping with the transport path and the position not overlapping with the transport path may be further included. In the exemplary embodiment, since the at least a part of the wall is disposed at the position overlapping with the transport path to form the processing space, it is possible to improve the plasma density per unit electric power supplied. It is also possible to carry in and carry out the workpiece by disposing the at least a part of the wall at the position not overlapping with the transport path.

In one exemplary embodiment, the wall may include a first ring-shaped plate having a first inner diameter and a second ring-shaped plate having a second inner diameter larger than the first inner diameter, and the elevating mechanism may be configured to move the first ring-shaped plate and the second ring-shaped plate individually along the vertical direction. According to the exemplary embodiment, since the diameter of the processing space can be changed, it is possible to adjust the plasma density in the processing space.

According to one aspect and various exemplary embodiments of the present disclosure, it is possible to improve the plasma density per unit supply electric power.

Hereinafter, various embodiments will be described in detail with reference to drawings. In each drawing, the same reference numeral will be assigned to the same or a corresponding portion and a repetitive description of the same or the corresponding portion will be omitted. A dimension ratio of each drawing does not necessarily coincide with an actual dimension ratio.

### First Exemplary Embodiment

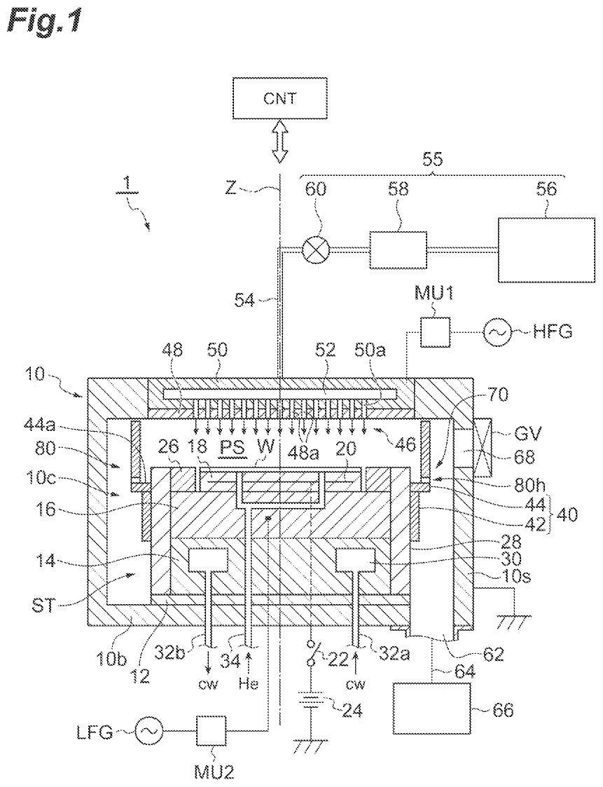

FIG. 1 is a view schematically illustrating a configuration of a plasma processing apparatus according to a first exemplary embodiment. A plasma processing apparatus 1 illustrated in FIG. 1 is a capacitive coupling type plasma processing apparatus. The plasma processing apparatus 1 includes a chamber body 10. The chamber body 10 has a substantially cylindrical shape and provides a chamber 10c as an internal space of the chamber body 10. The chamber body 10 is made of a material such as aluminum and includes a side wall 10s and a bottom wall 10b. The side wall 10s has the substantially cylindrical shape with an axis Z as the center. An inner wall surface of the side wall 10s is subjected to anodization. The chamber body 10 is grounded. The bottom wall 10b is connected to the lower end of the side wall 10s.

A stage ST is provided on the bottom wall 10b of the chamber body 10. The stage ST includes an insulation plate 12, a supporting base 14, a susceptor 16, and an electrostatic chuck 18, and is provided such that the center axis of the stage ST coincides with the axis Z. The insulation plate 12 is provided on the bottom wall 10b. The insulation plate 12 is made of, for example, ceramic. The supporting base 14 is provided on the insulation plate 12. The supporting base 14 has a substantially columnar shape. The susceptor 16 is provided on the supporting base 14. The susceptor 16 is made of a conductive material such as aluminum and configures a lower electrode.

The electrostatic chuck 18 is provided on the susceptor 16. The electrostatic chuck 18 has a structure in which an electrode 20 configured of a conductive film is sandwiched between insulation layers or insulation sheets. A DC power supply 24 is electrically connected to the electrode 20 of the electrostatic chuck 18 through a switch 22. The electrostatic chuck 18 generates electrostatic attraction force by a DC voltage from the DC power supply 24 and holds a workpiece W which is mounted on the electrostatic chuck 18 by the electrostatic attraction force. The workpiece W is, for example, a disk-shaped object such as a wafer. A focus ring 26 is disposed around the electrostatic chuck 18 and on the susceptor 16. An inner wall member 28 having a cylindrical shape is attached to the outer peripheral surfaces of the susceptor 16 and the supporting base 14. The inner wall member 28 is made of, for example, quartz.

A refrigerant flow path 30 is formed inside the supporting base 14. The refrigerant flow path 30 extends, for example, in a spiral shape with respect to the axis Z. A refrigerant cw (for example, cooling water) is supplied from a chiller unit provided outside the chamber body 10 to the refrigerant flow path 30 through a pipe 32a. The refrigerant supplied to the refrigerant flow path 30 is recovered into the chiller unit through a pipe 32b. A temperature of the refrigerant is adjusted by the chiller unit such that a temperature of the workpiece W is adjusted. Further, in the plasma processing apparatus 1, a heat transfer gas (for example, He gas) supplied through a gas supply line 34 is supplied between the upper surface of the electrostatic chuck 18 and the rear surface of the workpiece W.

An upper electrode 46 is provided on the top portion of the chamber body 10. The upper electrode 46 configures a ceiling according to one exemplary embodiment. The upper electrode 46 has a top plate 48 and a supporting body 50. A large number of gas ejection holes 48a are formed on the top plate 48. The top plate 48 is made of, for example, a silicon-based material such as Si or SiC. The supporting body 50 is a member that supports the top plate 48 in a detachable manner and is made of aluminum. A surface of the top plate 48 is subjected to the anodization.

A gas buffer chamber 52 is formed inside the supporting body 50. A large number of gas vent holes 50a are formed on the supporting body 50. The gas vent holes 50a extend from the gas buffer chamber 52 and communicate with the gas ejection holes 48a. A gas supply system 55 is connected to the gas buffer chamber 52 through a gas supply tube 54. The gas supply system 55 includes a gas source group 56, a flow rate controller group 58, and a valve group 60. The gas source group 56 includes a plurality of gas sources. The flow rate controller group 58 includes a plurality of flow rate controllers. The plurality of flow rate controllers may be, for example, mass flow rate controllers. The valve group 60 includes a plurality of valves. The plurality of gas sources of the gas source group 56 are connected to the gas supply tube 54 through the corresponding flow rate controllers of the flow rate controller group 58 and the corresponding valves of the valve group 60. The gas supply system 55 is configured so as to supply a processing gas from a selected gas source among the plurality of gas sources to the gas buffer chamber 52 at an adjusted flow rate. The gas introduced to the gas buffer chamber 52 is ejected from the gas ejection holes 48a to the chamber 10c.

A ring-shaped space is formed between the inner wall member 28 and the side wall 10s of the chamber body 10 in a plan view, and a bottom portion of the space is connected to an exhaust port 62 of the chamber body 10. An exhaust pipe 64 communicating with the exhaust port 62 is connected to the bottom portion of the chamber body 10. The exhaust pipe 64 is connected to an exhaust apparatus 66. The exhaust apparatus 66 has a vacuum pump such as a turbo molecular pump. The exhaust apparatus 66 reduces a pressure of the internal space of the chamber body 10 to a desired pressure. An opening 68 for carrying in and out the workpiece W is formed on the side wall of the chamber body 10. When the workpiece W is processed, the workpiece W is carried into the chamber 10c through the opening 68 and mounted on the upper surface of the electrostatic chuck 18. After the processing of the workpiece W is completed, the workpiece W is carried out from the chamber 10c through the opening 68. A gate valve GV for opening and closing the opening 68 is attached to the side wall of the chamber body 10.

The plasma processing apparatus 1 according to one exemplary embodiment may further include a base plate 40. The base plate 40 has the substantially cylindrical shape and is provided so as to surround the periphery of the stage ST. The center axis of the base plate 40 coincides with the axis Z. The base plate 40 includes a supporting portion 42 and a ring-shaped plate 44. The supporting portion 42 has a cylindrical shape with the axis Z as the center axis and is fixed to the outer peripheral surface of the inner wall member 28. The ring-shaped plate 44 is a plate body extending along the outer peripheral surface of the inner wall member 28 and provides an upper surface 44a having a ring shape with the axis Z as the center in a plan view. The ring-shaped plate 44 is fixed to the stage ST through the supporting portion 42. A movement mechanism 70 and a wall 80 are provided on the upper surface 44a of the ring-shaped plate 44. Details of the movement mechanism 70 and the wall 80 will be described below.

In one exemplary embodiment, the plasma processing apparatus 1 further includes a high frequency power supply HFG, a high frequency power supply LFG, a matching unit MU1, and a matching unit MU2. The high frequency power supply HFG generates high frequency electric power for plasma generation and supplies a frequency of 27 MHz or more, for example, high frequency electric power of 40 MHz to the upper electrode 46 through the matching unit MU1. The matching unit MU1 has a circuit that matches internal (or output) impedance of the high frequency power supply HFG to load impedance. The high frequency power supply LFG generates high frequency bias electric power for pulling an ion and supplies a frequency of 13.56 MHz or less, for example, high frequency bias electric power of 3 MHz to the susceptor 16 through the matching unit MU2. The matching unit MU2 has a circuit that matches internal (or output) impedance of the high frequency power supply LFG to the load impedance.

In one exemplary embodiment, the plasma processing apparatus 1 further includes a control unit Cnt. The control unit Cnt may be configured of, for example, a programmable computer. The control unit Cnt is connected to the switch 22, the high frequency power supply HFG, the matching unit MU1, the high frequency power supply LFG, the matching unit MU2, the gas supply system 55, the chiller unit, the DC power supply 24, the exhaust apparatus 66, and the movement mechanism 70.

The control unit Cnt operates according to a program based on an input recipe and sends a control signal. The control signal from the control unit Cnt can control opening and closing of the switch 22, electric power supply from the high frequency power supply HFG, impedance of the matching unit MU1, the electric power supply from the high frequency power supply LFG, impedance of the matching unit MU2, selection and a flow rate of a gas supplied from the gas supply system 55, a refrigerant flow rate and a refrigerant temperature of the chiller unit, the electric power supply of the DC power supply 24, exhaust of the exhaust apparatus 66, and an operation of the movement mechanism 70.

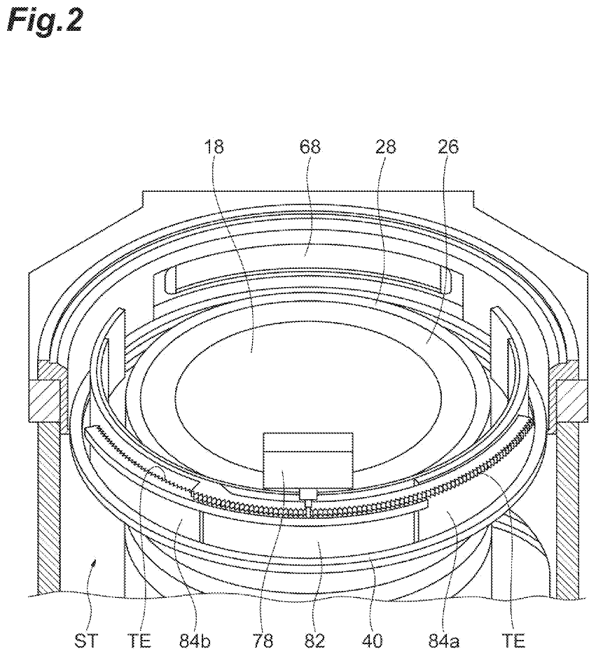

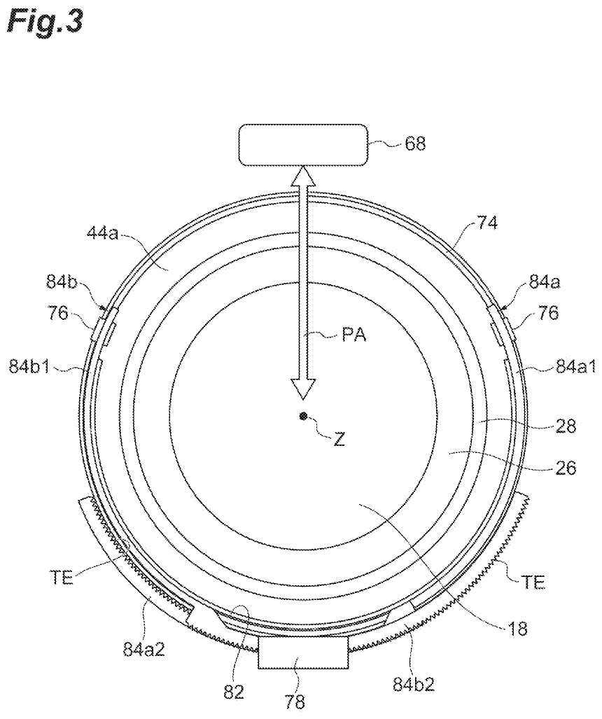

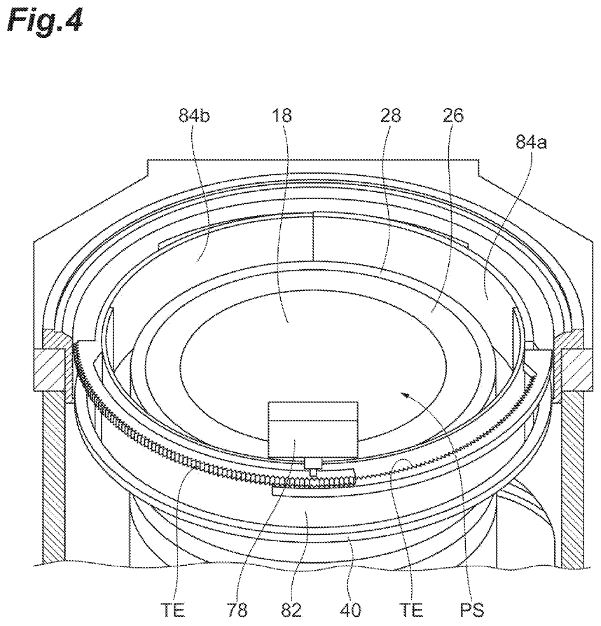

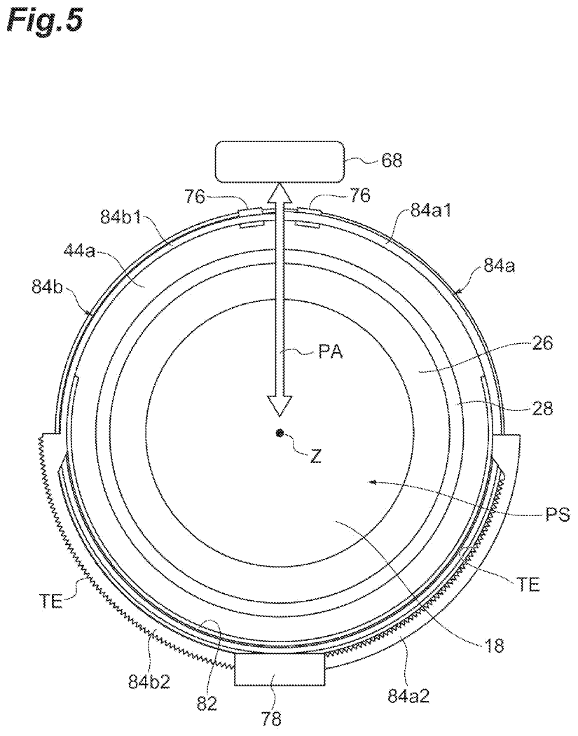

Next, the movement mechanism 70 and the wall 80 of the plasma processing apparatus 1 will be described with reference to FIGS. 2 to 5. The wall 80 is configured so as to have two states of an open state and a closed state. When the wall 80 is in the open state, the workpiece W can be carried in and carried out. FIG. 2 is a perspective view illustrating a part of a plasma processing apparatus 1 in a broken manner when the wall 80 is in the open state. FIG. 3 is a plan view of the stage ST and the wall 80 as viewed from above when the wall 80 is in the open state. On the other hand, when the wall 80 is in the closed state, a processing space PS having a volume smaller than the volume of the chamber 10c is formed in the chamber 10c. The processing space PS includes a space between the stage ST and the upper electrode 46. FIG. 4 is a perspective view illustrating the part of the plasma processing apparatus 1 in a broken manner when the wall 80 is in the closed state. FIG. 5 is a plan view of the stage ST and the wall 80 as viewed from above when the wall 80 is in the closed state.

As illustrated in FIGS. 3 and 5, the movement mechanism 70 has a guide rail 74, a slider 76, and a motor 78. The guide rail 74 is provided on the upper surface 44a of the ring-shaped plate 44 and has the ring shape with the axis Z as the center in a plan view. A plurality of sliders 76 are attached to the guide rail 74. The plurality of sliders 76 include bearings for rotation and are slidable along the guide rail 74 as a rolling body of the bearing rolls. The motor 78 generates driving force for driving movable plates 84a and 84b described below.

In one exemplary embodiment, the wall 80 includes one fixed plate 82 and two movable plates 84a and 84b. The fixed plate 82 and the movable plates 84a and 84b are plate bodies standing on the upper surface 44a of the ring-shaped plate 44 and are curved along the peripheral direction of the axis Z. Each of the fixed plate 82 and the movable plates 84a and 84b has an upper end surface in which each upper end surface faces the upper electrode 46 with a slight gap therebetween. The fixed plate 82 has a semi-circular ring shape in a plan view and extends along an inner side of the guide rail 74. The fixed plate 82 is provided on the side opposite to the opening 68 in the peripheral direction of the axis Z. In other words, the fixed plate 82 is fixed to the upper surface 44a of the ring-shaped plate 44 at a position not overlapping with a transport path PA extending between the processing space PS and the opening 68. The transport path PA represents a path through which the workpiece W passes when the workpiece W is carried into the chamber 10c and when the workpiece W is carried out from the chamber 10c.

Each of the movable plates 84a and 84b has a planar shape of the semi-circular ring shape and extends along the guide rail 74. The movable plates 84a and 84b are respectively provided on the plurality of sliders 76. Therefore, the movable plates 84a and 84b are configured so as to be movable along the guide rail 74 together with the plurality of sliders 76.

The movable plate 84a includes a plate-shaped portion 84a1 and a gear portion 84a2. The plate-shaped portion 84a1 is a plate body standing on the guide rail 74 and is curved along the guide rail 74. The upper end surface of the plate-shaped portion 84a1 faces the upper electrode 46 with a slight gap therebetween. The gear portion 84a2 is connected to the end portion in the peripheral direction of the plate-shaped portion 84a1. Teeth TE are formed on an inner peripheral surface of the gear portion 84a2.

The movable plate 84b includes a plate-shaped portion 84b1 and a gear portion 84b2. The plate-shaped portion 84b1 is a plate body standing on the guide rail 74 and is curved along the guide rail 74. The upper end surface of the plate-shaped portion 84b1 faces the upper electrode 46 with a slight gap therebetween. The gear portion 84b2 is connected to the end portion in the peripheral direction of the plate-shaped portion 84b1. The teeth TE are formed on an outer peripheral surface of the gear portion 84b2.

The gear portions 84a2 and 84b2 have an overlapped portion as viewed from the radial direction of the axis Z. In the overlapped portion, the gear portion 84a2 is located on the outer side than the gear portion 84b2 in the radial direction of the axis Z. An output shaft of the motor 78 is disposed between the gear portions 84a2 and 84b2. The output shaft is engaged with the teeth TE of the gear portions 84a2 and 84b2. The motor 78 is connected to the control unit Cnt and generates the driving force according to the control signal from the control unit Cnt. When the motor 78 is operated by the control signal from the control unit Cnt, the driving force is applied to the movable plates 84a and 84b, and the movable plates 84a and 84b move in opposite directions in the peripheral direction of the axis Z.

The wall 80 is switched between the closed state and the open state by moving the movable plate 84a and the movable plate 84b, which are parts of the wall 80, along the guide rail 74. For example, as illustrated in FIG. 3, in a case where the movable plate 84a and the movable plate 84b are disposed at the position not overlapping with the transport path PA, the wall 80 is in the open state. In the case where the wall 80 is in the open state, it is possible to carry the workpiece W into the chamber 10c through the opening 68 and the transport path PA to dispose the workpiece W on the electrostatic chuck 18, and to carry out the workpiece W on the electrostatic chuck 18 to the outside of the chamber 10c through the transport path PA and the opening 68. On the other hand, as illustrated in FIG. 5, in a case where the movable plate 84a and the movable plate 84b are disposed at a position overlapping with the transport path PA, the wall 80 is in the closed state. In the case where the wall 80 is in the closed state, the fixed plate 82 and the movable plates 84a and 84b cooperate to form a cylindrical body defining the processing space PS. Accordingly, a region where the plasma is generated in the plasma processing apparatus 1 is limited within the processing space PS. Since the volume of the processing space PS is smaller than the volume of the chamber 10c, high density plasma is generated in the processing space PS.

In one exemplary embodiment, a plurality of through-holes 80h for passing a gas in the processing space PS may be formed in each of the fixed plate 82 and the movable plates 84a and 84b of the wall 80. The through-holes 80h may extend, for example, in a plate thickness direction of the fixed plate 82 and the movable plates 84a and 84b. Each of the plurality of through-holes 80h may have a predetermined planar shape such as a circular shape, a long hole shape, a slit shape. In this manner, it is possible to exhaust the processing gas in the processing space PS by forming the plurality of through-holes 80h in the fixed plate 82 and the movable plates 84a and 84b. Further, in another exemplary embodiment, the plurality of through-holes may be formed in the upper surface 44a of the ring-shaped plate 44 in addition to the fixed plate 82 and the movable plates 84a and 84b. Since the gas in the processing space PS is exhausted also from the ring-shaped plate 44 by forming the plurality of through-holes in the upper surface 44a, it is possible to more efficiently exhaust the processing gas in the processing space PS.

### Second Exemplary Embodiment

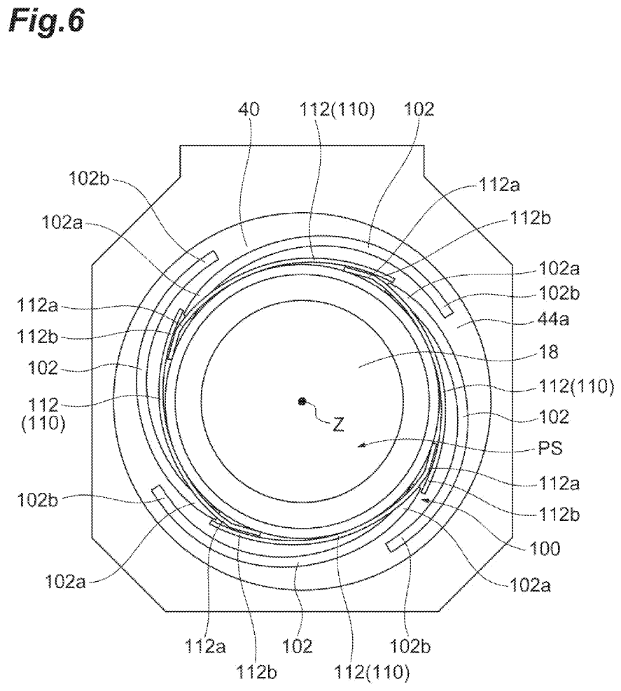

Next, a plasma processing apparatus according to a second exemplary embodiment will be described with reference to FIGS. 6 to 11. Hereinafter, differences from the first exemplary embodiment described above will be mainly described with regard to the second exemplary embodiment. The plasma processing apparatus according to the second exemplary embodiment includes a movement mechanism 100 and a wall 110 instead of the movement mechanism 70 and the wall 80. FIG. 6 is a plan view of the stage ST and the wall 110 of the plasma processing apparatus according to the second exemplary embodiment as viewed from above.

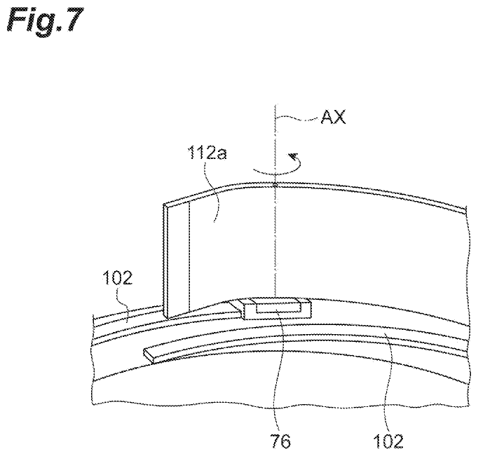

The movement mechanism 100 has a plurality of guide rails 102 and a plurality of sliders 76 (refer to FIG. 7). In the exemplary embodiment illustrated in FIG. 6, the movement mechanism 100 includes four guide rails 102. The plurality of guide rails 102 are disposed along the peripheral direction of the axis Z and are fixed on the upper surface 44a of the ring-shaped plate 44. Each of the plurality of guide rails 102 has one end portion 102a and the other end portion 102b and is curved in an arc shape between the one end portion 102a and the other end portion 102b in a plan view. Each of the plurality of guide rails 102 is disposed such that a distance to the axis Z (distance along the radial direction of the axis Z) increases from the one end portion 102a toward the other end portion 102b. Each of the one end portions 102a of the plurality of guide rails 102 overlaps the other end portion 102b of the adjacent guide rail 102 in the radial direction of the axis Z. The one end portion 102a is disposed more inward than the other end portion 102b in the radial direction of the axis Z.

As illustrated in FIG. 7, the plurality of sliders 76 are respectively provided on the plurality of guide rails 102. The plurality of sliders 76 are configured so as to be slidable along the corresponding guide rail 102 among the plurality of guide rails 102.

The wall 110 has a plurality of curved plates 112. The plurality of curved plates 112 are respectively provided on the plurality of guide rails 102. In the exemplary embodiment illustrated in FIG. 6, four curved plates 112 curved along the peripheral direction of the axis Z are provided. Each of the plurality of curved plates 112 has an upper end surface facing the upper electrode 46 with a slight gap therebetween. In one exemplary embodiment, a plurality of through-holes for passing the gas in the processing space PS defined by the plurality of curved plates 112 may be formed in each of the plurality of curved plates 112. The through-holes may extend, for example, in a plate thickness direction of the plurality of curved plates 112. Each of the plurality of through-holes may have a predetermined planar shape such as the circular shape, the long hole shape, the slit shape. Further, in another exemplary embodiment, the plurality of through-holes may be formed in the upper surface 44a of the ring-shaped plate 44 in addition to the plurality of curved plates 112.

Each of the plurality of curved plates 112 has a first end portion 112a and a second end portion 112b. As illustrated in FIG. 7, the first end portions 112a are connected to the sliders 76 so as to be rotatable with a rotation axis AX extending in a direction parallel to the axis Z as the center. On the other hand, the second end portions 112b of the plurality of curved plates 112 are free with respect to the slider 76 and the guide rail 102. That is, the second end portion 112b is a free end.

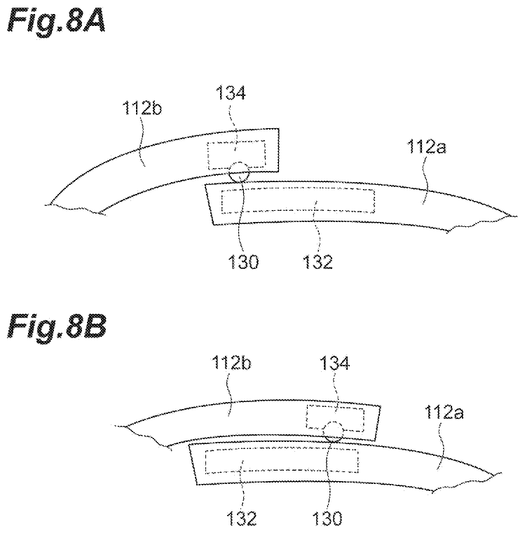

In one exemplary embodiment, as illustrated in FIGS. 8A and 8B, a first magnet 132 may be provided in the first end portion 112a of the curved plate 112 and a second magnet 134 may be provided in the second end portion 112b of the curved plate 112. The first magnet 132 and the second magnet 134 are respectively embedded in the first end portion 112a and the second end portion 112b. The first magnet 132 and the second magnet 134 have different polarities from each other. Therefore, magnetic force is applied to each of the first end portions 112a of the plurality of curved plates 112 so as to attract the second end portion 112b of the adjacent curved plate. Accordingly, the first end portion 112a and the second end portion 112b are connected to each other.

Further, in one exemplary embodiment, a ball member 130 may be fixed to the second end portion 112b. The ball member 130 is held, for example, by the second magnet 134 embedded in the second end portion 112b. The ball member 130 is interposed between the first end portion 112a and the second end portion 112b and contacts the first end portion 112a. Since the contact is a point contact, for example, when one second end portion 112b of the adjacent curved plate 112 moves from a position illustrated in FIG. 8A to a position illustrated in FIG. 8B, it is possible to reduce friction force generated between the first end portion 112a and the second end portion 112b. The ball member 130 may be fixed to the first end portion 112a and may contact the second end portion 112b. The ball member 130 may be fixed to one of the first end portion 112a and the second end portion 112b so as to be rotatable with a rotation axis extending in the direction parallel to the axis Z as the center.

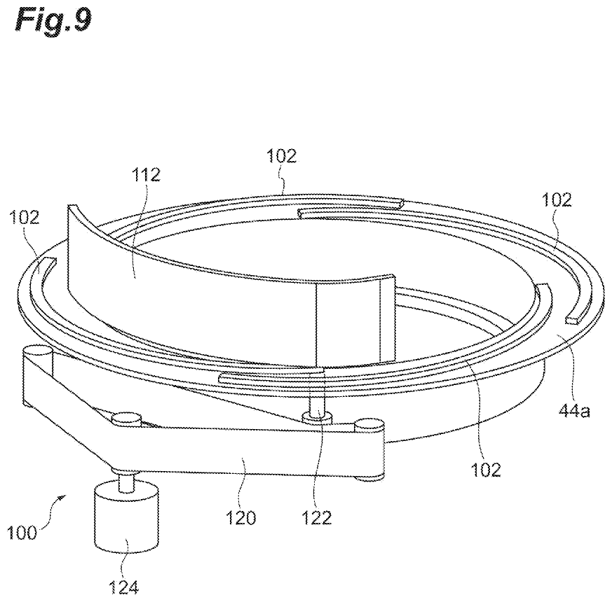

The movement mechanism 100 drives the plurality of curved plates 112 such that the first end portions 112a of the plurality of curved plates 112 move along the plurality of guide rails 102 together with the plurality of sliders 76. Hereinafter, the movement mechanism 100 will be described in detail with reference to FIG. 9. FIG. 9 is a perspective view schematically illustrating the movement mechanism 100. In FIG. 9, a part of a configuration is omitted for convenience of description. As illustrated in FIG. 9, the movement mechanism 100 further includes a rotation belt 120, a guide shaft 122, and a motor 124. A plurality of slot respectively extending along the outer side of the plurality of guide rails 102 are formed in the base plate 40 according to the exemplary embodiment. The slots are long holes penetrating the ring-shaped plate 44 in a plate thickness direction. The guide shaft 122 is inserted into each of the plurality of slots. An end portion of the guide shaft 122 is connected to the slider 76. The rotation belt 120 is bridged between the guide shaft 122 and the output shaft of the motor 124. Therefore, when the motor 124 is operated, the rotation belt 120 is driven and the guide shaft 122 moves along the outer side of each guide rail 102. Accordingly, the first end portions 112a of the plurality of curved plates 112 move along the plurality of guide rails 102 together with the sliders 76 connected to the guide shaft 122.

As illustrated in FIG. 6, the wall 110 according to the exemplary embodiment forms the cylindrical body by connecting the first end portions 112a of the plurality of curved plates 112 to the second end portions 112b of the adjacent curved plates 112. Accordingly, the processing space PS having the substantially columnar shape is defined the inner side of the wall 110. Since a region where the plasma is generated in the plasma processing apparatus 1 is limited to the processing space PS by the formation of the processing space PS, it is possible to improve plasma density generated in the processing space PS.

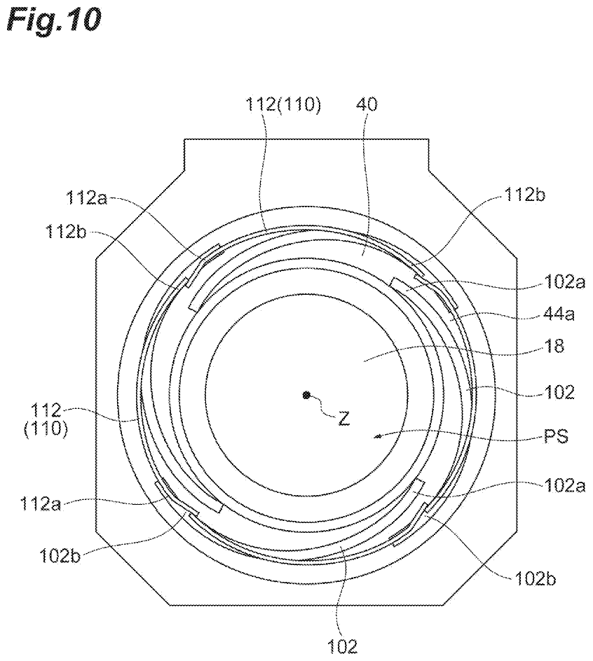

In the wall 110 according to the exemplary embodiment, the volume of the processing space PS can be changed by changing the first end portions 112a of the plurality of curved plates 112. For example, as illustrated in FIG. 10, in a case where the first end portions 112a of the plurality of curved plates 112 are moved so as to approach to the other end portions 102b of the guide rails 102, since the other end portions 102b are located on the outer side than the one end portions 102a, the first end portions 112a of the plurality of curved plates 112 move to the outer side in the radial direction of the axis Z. Consequently, the second end portions 112b which are the free ends also move to the outer side in the radial direction of the axis Z. Therefore, an inner diameter of the cylindrical body formed by the plurality of curved plates 112 increases and the volume of the processing space PS increases. On the contrary, in a case where the first end portions 112a of the plurality of curved plates 112 are moved so as to approach to the one end portions 102a of the guide rails 102, the inner diameter of the cylindrical body formed by the plurality of curved plates 112 decreases. As a result, the volume of the processing space PS decreases. Therefore, in the plasma processing apparatus 1, it is possible to adjust the plasma density in the processing space PS by changing the positions of the first end portions 112a of the plurality of curved plates 112.

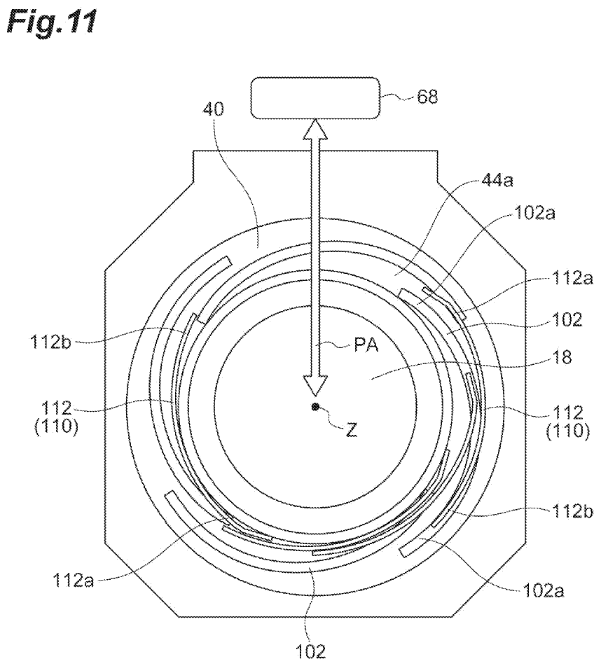

Further, as illustrated in FIG. 11, it is possible to retract the plurality of curved plates 112 to the position not overlapping with the transport path PA by moving the plurality of curved plates 112 along the plurality of guide rails 102 so as to be away from the opening 68. Accordingly, the wall 110 is in the open state. In this manner, it is possible to carry the workpiece W into the chamber 10c through the opening 68 and the transport path PA to dispose the workpiece W on the electrostatic chuck 18, and to carry out the workpiece W on the electrostatic chuck 18 to the outside of the chamber 10c through the transport path PA and the opening 68 by setting the wall 110 in the open state.

### Third Exemplary Embodiment

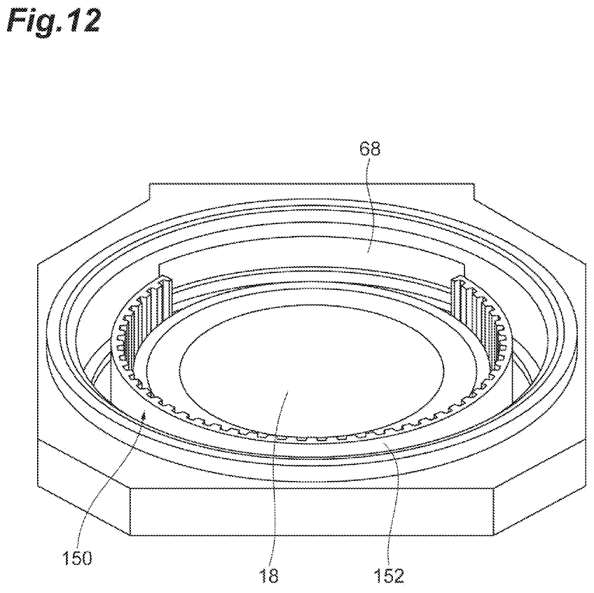

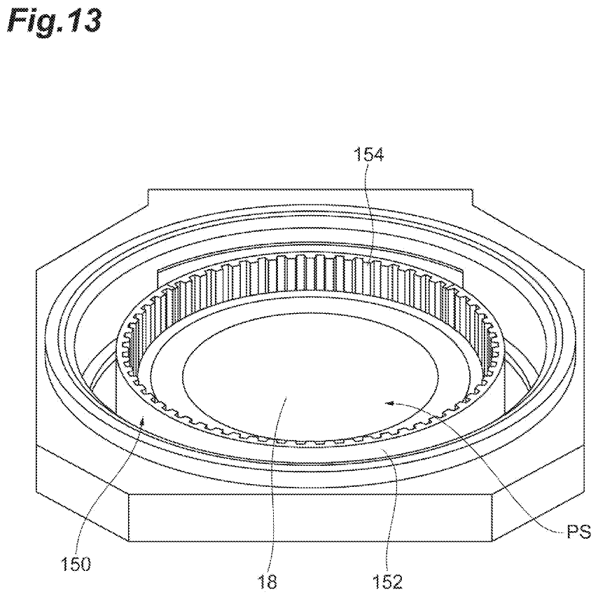

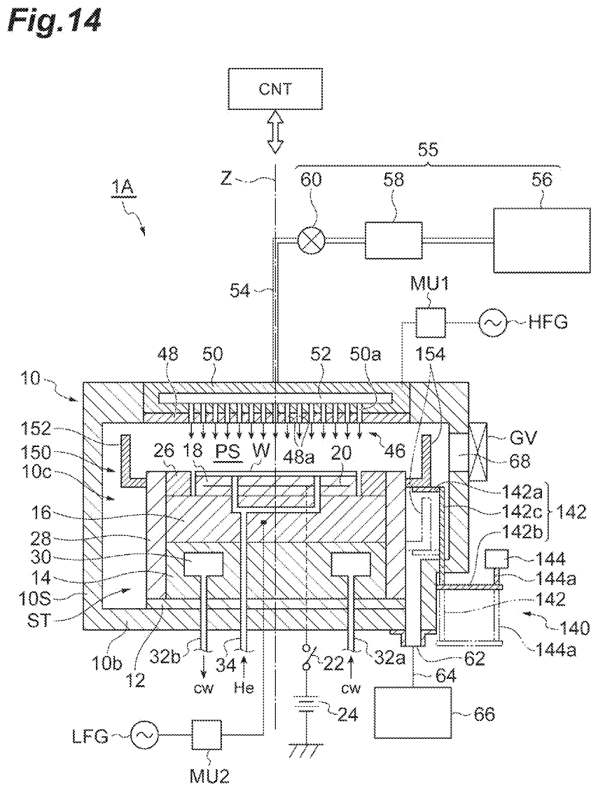

Next, a plasma processing apparatus according to a third exemplary embodiment will be described with reference to FIGS. 12 to 14. Hereinafter, differences from the first exemplary embodiment described above will be mainly described with regard to the third exemplary embodiment. A plasma processing apparatus 1A according to the third exemplary embodiment includes a movement mechanism 140 and a wall 150 instead of the movement mechanism 70 and the wall 80. FIGS. 12 and 13 are perspective views illustrating a part of the plasma processing apparatus 1A according to the third exemplary embodiment in a broken manner. FIG. 14 is a cross-sectional view schematically illustrating a configuration of the plasma processing apparatus 1A.

The wall 150 includes a fixed plate 152 and a movable plate 154. The fixed plate 152 is fixed to the inner wall member 28 and extends along the peripheral direction of the axis Z so as to partially surround the stage ST at the position not overlapping with the transport path PA. An upper end surface of the fixed plate 152 faces the upper electrode 46 with a slight gap therebetween. The movable plate 154 extends along the peripheral direction of the axis Z so as to partially surround the stage ST at a position overlapping with the opening 68 in the radial direction of the axis Z. The movable plate 154 is not fixed to the inner wall member 28 and is configured to be movable along the direction parallel to the axis Z, that is, the vertical direction of the plasma processing apparatus 1A. Therefore, the movable plate 154 can move between the position overlapping with the transport path PA and the position not overlapping with the transport path PA. FIG. 12 represents a state of the wall 150 in the case where the movable plate 154 is disposed at the position not overlapping with the transport path PA. FIG. 13 represents a state of the wall 150 in the case where the movable plate 154 is disposed at the position overlapping with the transport path PA. In the case where the movable plate 154 is disposed at the position overlapping with the transport path PA, the fixed plate 152 and the movable plate 154 cooperate to form the cylindrical body defining the processing space PS.

As illustrated in FIG. 13, inner peripheral surfaces of the fixed plate 152 and the movable plate 154 are uneven surfaces in which a recessed portion and a projected portion are alternately formed along the peripheral direction of the axis Z. On the other hand, the outer peripheral surfaces of the fixed plate 152 and the movable plate 154 are flat surfaces. A ratio between an anode and a cathode can be adjusted by setting the inner peripheral surfaces of the fixed plate 152 and the movable plate 154 facing the processing space PS to be the uneven surfaces. As a result, it is possible to adjust plasma intensity in the processing space PS. In one exemplary embodiment, the inner peripheral surfaces of the fixed plate 152 and the movable plate 154 may be the flat surfaces in the same manner as the outer peripheral surfaces. In another exemplary embodiment, the plurality of through-holes for passing the gas in the processing space PS may be formed in the fixed plate 152 and the movable plate 154. The through-holes may extend, for example, in a plate thickness direction of the fixed plate 152 and the movable plate 154. Each of the plurality of through-holes may have a predetermined planar shape such as the circular shape, the long hole shape, the slit shape.

The movement mechanism 140 will be described with reference to FIG. 14. The movement mechanism 140 functions as an elevating mechanism that moves the movable plate 154 along the vertical direction. The movement mechanism 140 has a connection portion 142 and a cylinder 144. The connection portion 142 includes a first plate 142a, a second plate 142b, and a shaft 142c. The first plate 142a supports the movable plate 154 thereon. The second plate 142b is provided outside the chamber 10c. The shaft 142c extends in the direction parallel to the axis Z and connects the first plate 142a and the second plate 142b. The cylinder 144 is, for example, an air cylinder and reciprocally moves a rod 144a along an axis Z direction by air pressure. The cylinder 144 is provided outside the chamber 10c and the rod 144a of the cylinder 144 is connected to the second plate 142b. Therefore, the movable plate 154 is driven along the vertical direction through the connection portion 142 due to the reciprocal movement of the rod 144a in the vertical direction. In this manner, the movement mechanism 140 changes a position of the rod 144a in the vertical direction to move the movable plate 154 between the position overlapping with the transport path PA and the position not overlapping with the transport path PA. In one exemplary embodiment, the cylinder 144 is connected to the control unit Cnt and is configured to be able to adjust the position of the rod 144a in the vertical direction according to the control signal from the control unit Cnt.

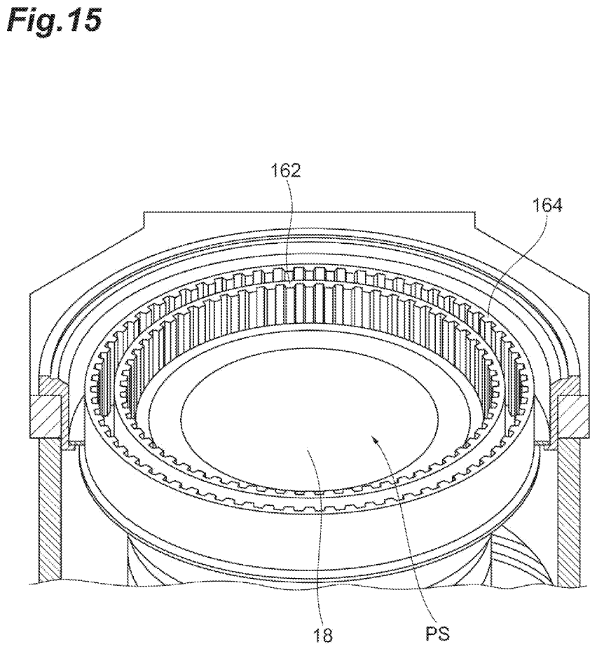

Hereinafter, a modification example of the plasma processing apparatus 1A will be described with reference to FIG. 15. As illustrated in FIG. 15, the plasma processing apparatus according to the modification example includes the first ring-shaped plate 162 and the second ring-shaped plate 164. The first ring-shaped plate 162 and the second ring-shaped plate 164 are provided between the stage ST and the side wall 10s and has the cylindrical shape with the axis Z as the center. The first ring-shaped plate 162 has a first inner diameter. The second ring-shaped plate 164 has a second inner diameter larger than the first inner diameter. That is, the second ring-shaped plate 164 is provided so as to surround the first ring-shaped plate 162.

As illustrated in FIG. 15, inner peripheral surfaces of the first ring-shaped plate 162 and the second ring-shaped plate 164 are uneven surfaces in which recessed portions and projected portions are alternately formed along the peripheral direction of the axis Z. On the other hand, the outer peripheral surfaces of the first ring-shaped plate 162 and the second ring-shaped plate 164 are flat surfaces. In one exemplary embodiment, the inner peripheral surfaces of the first ring-shaped plate 162 and the second ring-shaped plate 164 may be the flat surfaces in the same manner as the outer peripheral surfaces. In another exemplary embodiment, the plurality of through-holes for passing the gas in the processing space PS may be formed in the first ring-shaped plate 162 and the second ring-shaped plate 164. The through-holes may extend, for example, in a plate thickness direction of the first ring-shaped plate 162 and the second ring-shaped plate 164. Each of the plurality of through-holes may have a predetermined planar shape such as the circular shape, the long hole shape, the slit shape.

The movement mechanisms 140 described above are respectively connected to the first ring-shaped plate 162 and the second ring-shaped plate 164. The movement mechanisms 140 individually move the first ring-shaped plate 162 and the second ring-shaped plate 164 in the vertical direction between the position overlapping with the transport path PA and the position not overlapping with the transport path PA. Therefore, for example, in a case where the first ring-shaped plate 162 is disposed at the position overlapping with the transport path PA and the second ring-shaped plate 164 is disposed at the position not overlapping with the transport path PA, a processing space PS having volume corresponding to the first inner diameter is formed by the movement mechanism 140. In a case where the first ring-shaped plate 162 is disposed at the position not overlapping with the transport path PA and the second ring-shaped plate 164 is disposed at the position overlapping with the transport path PA, a processing space PS having volume corresponding to the second inner diameter is formed by the movement mechanism 140. Therefore, in the plasma processing apparatus according to the modification example, the volume of the processing space PS can be adjusted by individually adjusting the positions of the first ring-shaped plate 162 and the second ring-shaped plate 164 in the vertical direction.

The plasma processing apparatuses according to various exemplary embodiments are described. However, the present disclosure is not limited to the exemplary embodiments described above and various modification aspects can be configured within the scope not changing the gist of the disclosure. For example, in the first and second exemplary embodiments, the movable plate 84a and the curved plate 112 are moved using the slider 76. However, the slider 76 may not necessarily be included as long as the movable plate 84a and the curved plate 112 can be moved. For example, a pair of magnetic poles configured of N-pole and S-pole may be disposed in the guide rails 74 and 102 to move the movable plate 84a and the curved plate 112 using a linear motor.

The plasma processing apparatuses 1 and 1A described above are the capacitive coupling type plasma processing apparatuses. However, the plasma processing apparatus according to various exemplary embodiments and modification aspects thereof may be an electron cyclotron resonance (ECR) type plasma processing apparatus, an inductive coupling type plasma processing apparatus, or a plasma processing apparatus using a surface wave such as a microwave in the plasma generation.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber body providing a chamber, the chamber body including a side wall having an opening through which a workpiece is carried into the chamber or carried out from the chamber;
a stage provided in the chamber;
a ceiling facing the stage;
a gas supply system configured to supply a processing gas to the chamber;
a power supply configured to supply electric power for generating plasma of the processing gas; and
a wall that forms a processing space having a volume smaller than a volume of the chamber in the chamber, the processing space including a space between the stage and the ceiling,
wherein at least a part of the wall is movable between a position overlapping with a transport path extending between the processing space and the opening and a position not overlapping with the transport path, and the wall forms the processing space when the at least a part of the wall is disposed at the position overlapping with the transport path.

2. The plasma processing apparatus according to claim 1, further comprising:
an exhaust apparatus connected to the chamber,
wherein a plurality of through-holes through which a gas in the processing space passes are formed in the wall.

3. The plasma processing apparatus according to claim 1,
wherein the wall includes a fixed plate fixed to the position not overlapping with the transport path and a movable plate,
wherein the plasma processing apparatus further comprises a movement mechanism configured to move the movable plate between the position overlapping with the transport path and the position not overlapping with the transport path, and
wherein the fixed plate and the movable plate cooperate to form a cylindrical body defining the processing space when the movable plate is disposed at the position overlapping with the transport path.

4. The plasma processing apparatus according to claim 3,
wherein the movement mechanism includes
a base plate provided to surround a periphery of the stage,
a ring-shaped guide rail provided on the base plate,
a slider provided on the guide rail to be movable along the guide rail, and
a motor configured to drive the movable plate,
wherein the fixed plate is fixed on the base plate along the guide rail, and
wherein the movable plate is connected to the slider along the guide rail.

5. The plasma processing apparatus according to claim 1, further comprising:
a base plate provided to surround a periphery of the stage;
a plurality of guide rails provided on the base plate, each of the plurality of guide rails having one end portion and another end portion and extending in an arc shape between the one end portion and the other end portion such that a distance from a center axis of the stage increases from the one end portion toward the other end portion, wherein in each of the plurality of guide rails, the one end portion overlaps with the other end portion of an adjacent guide rail among the plurality of guide rails in a radial direction with respect to the center axis, and the one end portion is located more inward than the other end portion in the radial direction; and
a plurality of sliders respectively provided on the plurality of guide rails, each of the plurality of sliders being slidable along a corresponding guide rail among the plurality of guide rails,
wherein the wall includes a plurality of curved plates provided on the plurality of guide rails, each of the plurality of curved plates has a first end portion and a second end portion, the first end portion of each of the plurality of curved plates is connected to a corresponding slider among the plurality of sliders to be rotatable with a rotation axis extending in a direction parallel to the center axis as a center, and the second end portion of each of the plurality of curved plates is a free end.

6. The plasma processing apparatus according to claim 5,
wherein a first magnet is provided in the first end portion, and a second magnet having a polarity different from a polarity of the first magnet is provided in the second end portion.

7. The plasma processing apparatus according to claim 5, further comprising:
a ball member fixed to one end portion of the first end portion and the second end portion of each of the plurality of curved plates and configured to contact the other end portion of the first end portion and the second end portion of an adjacent curved plate among the plurality of curved plates.

8. The plasma processing apparatus according to claim 1, further comprising:
an elevating mechanism configured to move the at least a part of the wall along a vertical direction between the position overlapping with the transport path and the position not overlapping with the transport path.

9. The plasma processing apparatus according to claim 8,
wherein the wall includes a first ring-shaped plate having a first inner diameter and a second ring-shaped plate having a second inner diameter larger than the first inner diameter, and
wherein the elevating mechanism is configured to move the first ring-shaped plate and the second ring-shaped plate individually along the vertical direction.
